(19) United States
(12) Patent Application Publication
(10) Pub. No.: US 2015/0091011 A1
(43) Pub. Date: Apr. 2, 2015

(54) DISPLAY DEVICE AND METHOD FOR FABRICATING THE SAME

(71) Applicant: SAMSUNG DISPLAY CO., LTD., Yongin-City (KR)

(72) Inventors: Koichi Sugitani, Hwaseong-si (KR); Hoon Kang, Suwon-si (KR); Jae Sung Kim, Suwon-si (KR); Jin Ho Ju, Seoul (KR)

(73) Assignee: SAMSUNG DISPLAY CO., LTD., Yongin-City (KR)

(21) Appl. No.: 14/226,784

(22) Filed: Mar. 26, 2014

(30) Foreign Application Priority Data
Oct. 1, 2013 (KR) 10-2013-0117354

(51) Int. Cl. G02F 1/1333; H01L 27/12

(52) U.S. Cl. CPC G02F 1/133305; G02F 1/133345; H01L 27/124; H01L 27/1248; H01L 27/1259; G02F 2001/133357
USPC 257/72; 438/158

(57) ABSTRACT

A display device and a method for fabricating a display device are provided. According to one embodiment of the present invention, a display device includes a substrate, an insulating layer arranged on the substrate, a wiring pattern arranged on the insulating layer, an organic layer arranged on the wiring pattern, and a contact hole penetrating the organic layer to expose at least a portion of the wiring pattern. The side wall of the organic layer that defines the contact hole includes a first side wall portion and a second side wall portion, and a value obtained by dividing a vertical distance of the first side wall portion by a horizontal distance of the first side wall portion is different from a value obtained by dividing a vertical distance of the second side wall portion by a horizontal distance of the second side wall portion.

### CROSS-REFERENCE TO RELATED APPLICATION

This application claims priority to and the benefit of Korean Patent Application No. 10-2013-0117354, filed on Oct. 1, 2013, in the Korean Intellectual Property Office, the disclosure of which is incorporated herein in its entirety by reference.

### BACKGROUND

1. Field

The following description relates to a display device and a method for fabricating the same.

2. Description of the Prior Art

A liquid crystal display is a flat panel display that has been widely used, and is a display device which adjusts the quantity of penetrating light by realigning liquid crystal molecules of a liquid crystal layer through application of a voltage to an electrode.

The liquid crystal display has the advantage of easy thin-film formation, but has the disadvantage that its side visibility is inferior in comparison to its front visibility. To overcome this, various methods for aligning and driving liquid crystals have been developed. As a method for implementing a wide viewing angle, a liquid crystal display, in which a pixel electrode and a common electrode are formed on one substrate, has been in the spotlight.

In a display device including such a liquid crystal display, at least one contact hole is formed. In such a contact hole, electrodes or various kinds of wirings are electrically connected to each other, and it is important to both improve the coverage of a conductive material that is arranged on the contact hole and to accurately expose a conductive material that is arranged on a lower portion of the contact hole. There is a trade-off relationship between the two requirements, and if importance is given to one over the other, the other tends to be relatively insufficient or short. However, in order to produce a high-efficiency display device, both of the requirements are important, and thus various technical attempts have been made to solve such a problem.

### SUMMARY

An aspect of the present invention is directed toward a display device on which at least one contact hole is formed and a method for fabricating the same.

An aspect of the present invention is directed toward a display device which may improve contact coverage and reduce or prevent contact inferiority through a certain opening of a contact hole. Another aspect of the present invention is directed toward a method for fabricating a display device which may improve contact coverage and reduce or prevent contact inferiority through a certain opening of a contact hole.

Additional enhancements, subjects, and features of the invention will be set forth in part in the description which follows and in part will become apparent to those having ordinary skill in the art upon examination of the following or may be learned from practice of the invention.

In an embodiment of the present invention, a display device includes a substrate, an insulating layer on the substrate, a wiring pattern on the insulating layer, an organic layer on the wiring pattern, and a contact hole penetrating the organic layer to expose at least a portion of the wiring pattern. A side wall of the organic layer defining (partitioning) the contact hole includes a first side wall portion and a second side wall portion, and a value (an average inclination of the first side wall portion) obtained by dividing a vertical distance of the first side wall portion by a horizontal distance of the first side wall portion is different from a value (an average inclination of the second side wall portion obtained by dividing a vertical distance of the second side wall portion by a horizontal distance of the second side wall portion.

According to another embodiment of the present invention, a method for fabricating a display device includes forming a gate insulating layer on a substrate with a gate electrode, forming a semiconductor layer on the gate insulating layer, forming a drain electrode to extend from the semiconductor layer to an upper portion of the gate insulating layer; forming an organic layer on the drain electrode to cover the drain electrode; forming a contact hole to expose at least a portion of the drain electrode through penetrating the organic layer, the contact hole being defined (partitioned) by a first side wall portion, a second side wall portion, and a bottom surface; curing the second side wall portion through irradiating ultraviolet rays onto a lower surface of the substrate; and lowering a value of an average inclination of the first side wall portion through curing the organic layer.

According to the embodiments of the present invention, at least the following effects may be achieved.

The average inclination of the first side wall is lowered, and thus the coverage of the contact layer arranged on the organic layer may be improved.

Further, since the average inclination of the second side wall is effectively maintained (kept) high, the opening of the contact hole is accurately opened to reduce or prevent any contact inferiority.

The effects according to embodiments of the present invention are not limited to the contents as exemplified above, but further various effects are included in the description.

### BRIEF DESCRIPTION OF THE DRAWINGS

The above and other objects, features and enhancements of the present invention will be more apparent from the following detailed description taken in conjunction with the accompanying drawings, in which:

FIG. 1 is a partial plan view of a display device according to an embodiment of the present invention;

FIG. 2 is a cross-sectional view cut along the line I-I′ of FIG. 1;

FIG. 3 is a reference diagram for the definition of some terms;

FIG. 4 is a partial plan view of a display device according to another embodiment of the present invention;

FIG. 5 is a cross-sectional view cut along the line II-II′ of FIG. 4;

FIG. 6 is a partial plan view of a display device according to still another embodiment of the present invention;

FIG. 7 is a cross-sectional view of the display device of FIG. 6; and

FIGS. 8 to 12 are cross-sectional views illustrating a method for fabricating a display device according to an embodiment of the present invention.

### DETAILED DESCRIPTION

The aspects and features of the present invention and methods for achieving the aspects and features will be apparent by referring to the embodiments to be described in detail with reference to the accompanying drawings. However, the present invention is not limited to the embodiments disclosed hereinafter, but may be implemented in diverse forms. The matters defined in the description, such as the detailed construction and elements, are specific details provided to assist those of ordinary skill in the art in a comprehensive understanding of the invention, and the present invention should only be defined within the scope of the appended claims, and equivalents thereof.

The term “on” that is used to describe that an element (or a layer) is on another element (or another layer) includes both a case where the element is located directly on the other element and a case where an element is located on another element with one or more intermediate layers or elements therebetween. In the entire description of the present invention, the same or like drawing reference numerals are used for the same or like elements throughout various figures.

Although the terms “first”, “second”, and so forth are used to describe diverse constituent elements, such constituent elements are not limited by the terms. The terms are used only to discriminate a constituent element from other constituent elements. Accordingly, in the following description, a first constituent element may be a second constituent element. Expressions such as “at least one of,” when preceding a list of elements, modify the entire list of elements and do not modify the individual elements of the list. Further, the use of “may” when describing embodiments of the present invention refers to “one or more embodiments of the present invention.”

Hereinafter, embodiments of the present invention will be described with reference to the drawings.

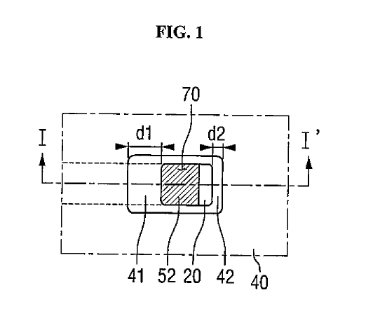

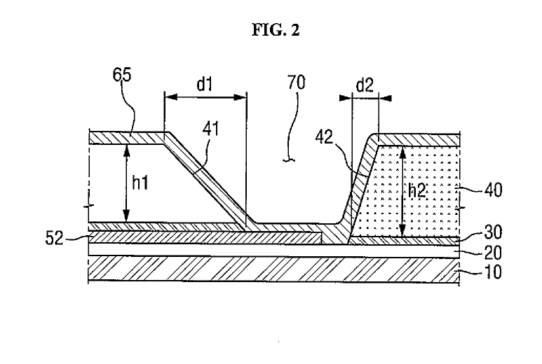

FIG. 1 is a partial plan view of a display device according to an embodiment of the present invention, and FIG. 2 is a cross-sectional view cut along the line I-I′ of

FIG. 1.

Referring to FIGS. 1 and 2, a display device according to an embodiment of the present invention includes a substrate 10, an insulating layer 20 arranged on the substrate 10, a wiring pattern 52 arranged on the insulating layer 20, an organic layer 40 arranged on the wiring pattern 52, and a contact hole 70 penetrating the organic layer 40 to expose at least a portion of the wiring pattern 52. The side wall of the organic layer 40 that defines (or partitions) the contact hole 70 includes a first side wall portion 41 and a second side wall portion 42, and a value obtained by dividing a vertical distance h1 of the first side wall portion 41 by a horizontal distance d1 of the first side wall portion 41 is different from a value obtained by dividing a vertical distance h2 of the second side wall portion 42 by a horizontal distance d2 of the second side wall portion 42 (e.g., a ratio of the vertical distance h1 to the horizontal distance d1 is different from (e.g., less than) a ratio of the vertical distance h2 to the horizontal distance d2).

The substrate 10 is an insulating substrate, and may be formed of glass or plastic. In the description, it may be understood that the substrate 10 includes not only a flat substrate but also a flexible substrate that may allow bending, folding, and/or rolling to be performed.

The insulating layer 20 may be formed on the substrate 10. The insulating layer 20 may include silicon nitride (SiNx) or silicon oxide (SiOx), but the material of the insulating layer 20 is not limited thereto. The insulating layer 20 may have a single-layer structure, but is not limited thereto. The insulating layer 20 may have a multilayer structure that includes at least two insulating layers having different physical properties. In an example embodiment, the insulating layer 20 may be a gate insulating layer, but is not limited thereto. The gate insulating layer will be described in more detail later.

The wiring pattern 52 may be formed on the insulating layer 20. The wiring pattern 52 may be made of a metal material having a suitable electrical conductivity. The wiring pattern 52 may be formed to include at least one material selected from the group consisting of aluminum based metal (such as aluminum (Al) or an aluminum alloy), silver based metal (such as silver (Ag) or a silver alloy), copper based metal (such as copper (Cu) or a copper alloy), molybdenum based metal (such as molybdenum (Mo) or a molybdenum alloy), chrome (Cr), tantalum (Ta), and titanium (Ti). In another example embodiment, the wiring pattern 52 may be made of indium tin oxide (ITO) or indium zinc oxide (IZO). However, the material of the wiring pattern 52 is not limited thereto.

In the description, the term “wiring pattern” may be understood broadly. That is, in the description, the wiring pattern 52 may include various kinds of signal lines, electrodes, and a pad portion as a whole.

A passivation layer 30 may be arranged on the wiring pattern 52. The passivation layer 30 may include an organic insulating material or an inorganic insulating material. However, in an example embodiment, the passivation layer 30 may be omitted.

The organic layer 40 may be arranged on the passivation layer 30. The organic layer 40 may be relatively thicker than the passivation layer 30. In an example embodiment, the organic layer 40 may be a planarization film. That is, the surface of the organic layer 40 may be flat. The organic layer 40 may be arranged on a display region where a plurality of pixels are positioned, and may not be positioned on a peripheral region where a gate pad portion 90 or a data pad portion 80 is formed, but is not limited thereto. Further, the thickness of the organic layer 40 in the peripheral region may be different from the thickness of the organic layer 40 in the display region, but the thickness of the organic layer 40 is not limited thereto. Further, in an example embodiment, the organic layer 40 may be omitted.

On the organic layer 40, the contact hole 70, which penetrates the organic layer 40 and exposes at least a portion of the wiring pattern 52, may be formed. If the passivation layer 30 is formed on the wiring pattern 52, the contact hole 70 may penetrate the organic layer 40 and the passivation layer 30, and expose at least a portion of the wiring pattern 52. Further, in an example embodiment in which the second side wall portion 42 does not overlap the wiring pattern 52, the contact hole 70 may expose at least a portion of the insulating layer 20.

The contact hole 70 may be defined (partitioned) by a side wall of the organic layer 40. The side wall of the organic layer 40 may include a first side wall portion 41 and a second side wall portion 42. That is, the contact hole 70 may be defined by a bottom surface, the first side wall portion 41, and the second side wall portion 42. Further, the first side wall portion 41 and the second side wall portion 42 may each include an inclined portion (or inclination portion) that is inclined downward toward the bottom surface. Further, in an example embodiment in which the passivation layer 30 is arranged on the wiring pattern 52, the first side wall portion 41 and the second side wall portion 42 may further include the side wall of the passivation layer 30.

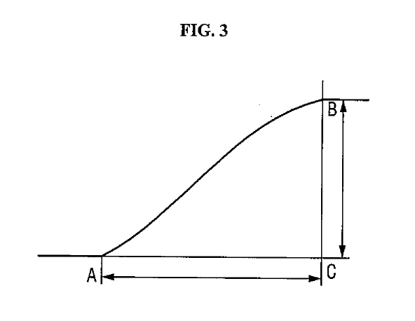

For convenience in explanation, terms (i.e., “horizontal distance” and “vertical distance”) are defined. For definition of these terms, FIG. 3 is referred to.

FIG. 3 is a reference diagram for definition of the terms “horizontal distance” and “vertical distance”.

Referring to FIG. 3, in the description, a horizontal distance refers to a distance in a horizontal direction when an upper end point and a lower end point of the inclined portion are (projected) on the same (horizontal) plane, that is, a length of a line segment AC in FIG. 3. A vertical distance refers to a distance in a vertical direction when the upper end point and the lower end point of the inclined portion are (projected) on the same (vertical) plane, that is, a length of a line segment BC in FIG. 3. An average inclination refers to a value obtained by dividing the vertical distance (h) of the inclined portion by the horizontal distance (d) of the inclined portion. Hereinafter, explanation will be made based on this.

The first side wall portion 41 may be arranged on the wiring pattern 52. That is, the first side wall portion 41 may be arranged to overlap the wiring pattern 52. In other words, a lower end of the first side wall portion 41 may be arranged on an inner side rather than an end portion of the wiring pattern 52. The second side wall portion 42 may be arranged on the insulating layer 20 or the passivation layer 30 without overlapping the wiring pattern 52. That is, a lower end of the second side wall portion 42 may be spaced apart from the end portion of the wiring pattern 52 for a set or predetermined distance, but is not limited thereto. A part of the second side wall portion 42 may partially overlap the end portion of the wiring pattern 52.

An average inclination of the first side wall portion 41 and an average inclination of the second side wall portion 42 may be different from each other. That is, a value obtained by dividing the vertical distance h1 of the first side wall portion 41 by the horizontal distance d1 of the first side wall portion 41 may be different from a value obtained by dividing the vertical distance h2 of the second side wall portion 42 by the horizontal distance d2 of the second side wall portion 42. In an example embodiment, the average inclination of the first side wall portion 41 may be smaller than that of the second side wall portion 42. That is, the horizontal distance d1 of the first side wall portion 41 may be larger than the horizontal distance d2 of the second side wall portion 42. In this case, the average inclination of the first side wall portion 41 may be less in value than the average inclination of the second side wall portion 42. Here, as described above, the organic layer 40 is a planarization film, and thus the height of the upper surface of the organic layer 40 may be substantially the same. That is, the vertical distance h1 of the first side wall portion 41 may be substantially equal to the vertical distance h2 of the second side wall portion 42, or the vertical distance h1 of the first side wall portion 41 may be slightly larger than the vertical distance h2 of the second side wall portion 42. However, a difference between the horizontal distance d1 of the first side wall portion 41 and the horizontal distance d2 of the second side wall portion 42 may be relatively larger than a difference between the vertical distance h1 of the first side wall portion 41 and the vertical distance h2 of the second side wall portion 42. That is, the average inclination of the first side wall portion 41 and the average inclination of the second side wall portion 42 may be influenced by the horizontal distances of the first side wall portion 41 and the second side wall portion 42, respectively. That is, the influence that is exerted on the difference in the average inclination of the first side wall portion 41 and the second side wall portion 42 by the difference in vertical distance between the first side wall portion 41 and the second side wall portion 42 may be smaller (or less) than the influence that is exerted on the difference in the average inclination of the first side wall portion 41 and the second side wall portion 42 by the difference in horizontal distance between the first side wall portion 41 and the second side wall portion 42.

In an example embodiment, the glass transition temperature Tg of the first side wall portion 41 may be different from the glass transition temperature of the second side wall portion 42. This is because in a process of irradiating the UV rays onto a rear surface of the substrate 10 (to be described later), ultraviolet (UV) rays irradiated onto the first side wall portion 41 are intercepted by the wiring pattern 52, but UV rays irradiated onto the second side wall portion 42 are not intercepted, and are irradiated onto the second side wall portion 42 to cure the second side wall portion 42. That is, the glass transition temperature of the second side wall portion 42 may be higher than the glass transition temperature of the first side wall portion 41. If the curing temperature is high, the first side wall portion 41 falls (falls down) at least partly to lower the average inclination value in a curing process to be described later, whereas in comparison to the first side wall portion 41, the second side wall portion 42 may keep the average inclination value approximately or about the same as that prior to the curing. The details thereof will be described later.

FIGS. 1 and 2 illustrate an example embodiment where the first side wall portion 41 is arranged on the left side of each drawing and the second side wall portion 42 is arranged on the right side of each drawing. However, the positions and the number of the first side wall portions 41 and the second side wall portions 42 are not limited thereto, and the side wall of the organic layer 40 may include at least one first side wall portion 41 and at least one second side wall portion 42. Further, the arrangement of the first side wall portion 41 and the second side wall portion 42 is not limited thereto, but may be arranged in various positions.

FIGS. 1 and 2 illustrate an example embodiment where the contact hole 70 is in a rectangular shape. The shape of the contact hole 70 is not limited thereto, and in another example embodiment, the contact hole 70 may be in a circular shape. If the contact hole 70 is circular, the circular contact hole 70 may be divided into at least two sections, and the first side wall portion 41 and the second side wall portion 42 may be arranged in the respective sections so that the first side wall portion 41 and the second side wall portion 42 coexist.

FIGS. 1 and 2 illustrate an example embodiment where the inclined portion of the first side wall portion 41 and the second side wall portion 42 is planar (La, has a flat surface), but is not limited thereto. The inclined portion of the first side wall portion 41 and the inclined portion of the second side wall portion 42 may at least partly have a curved surface.

On the organic layer 40, a contact layer 65, which covers the first side wall portion 41, the second side wall portion 42, and the bottom surface, may be formed. That is, the contact layer 65 may come in contact with the wiring pattern 52, and may be electrically connected to the wiring pattern 52.

The contact layer 65 may be made of a metal material having suitable electrical conductivity. The contact layer 65 may be formed to include at least one material selected from the group consisting of aluminum based metal (such as aluminum (Al) or an aluminum alloy), silver based metal (such as silver (Ag) or a silver alloy), copper based metal (such as copper (Cu) or a copper alloy), molybdenum based metal (such as molybdenum (Mo) or a molybdenum alloy), chrome (Cr), tantalum (Ta), and titanium (Ti). In another example embodiment, the contact layer 65 may be made of indium tin oxide (ITO) or indium zinc oxide (IZO). However, the material of the contact layer 65 is not limited thereto.

As described above, if the average inclination values of the first side wall portion 41 and the second side wall portion 42 differ from each other, the step coverage of the contact layer 65 is improved, and the contact inferiority due to clogging of the opening may be reduced or prevented from occurring.

Hereinafter, other embodiments of the present invention will be described. The same reference numerals are used for the same configurations as the configurations described above, and the duplicate explanation thereof will not be repeated or will be simplified.

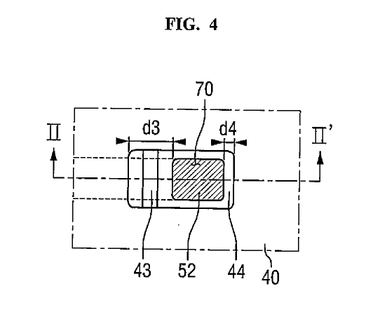

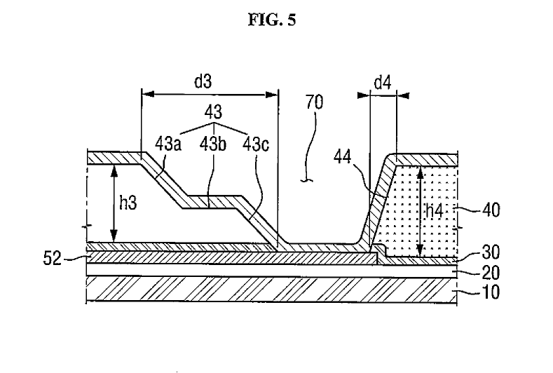

FIG. 4 is a partial plan view of a display device according to another embodiment of the present invention, and FIG. 5 is a cross-sectional view cut along the line II-II′ of FIG. 4.

Referring to FIGS. 4 and 5, the display device according to this embodiment is different from the display device according to the embodiment of FIG. 1 in that the display device according to this embodiment is in shape of a stair (a set of steps) having step heights.

As described above, the average inclination of the first side wall portion 43 may be different from the average inclination of the second side wall portion 44, and in an example embodiment, the average inclination of the first side wall portion 43 may be smaller than the average inclination of the second side wall portion 44. In an embodiment of FIG. 4, the average inclination of the first side wall portion 43 corresponds to a value obtained by dividing the vertical distance h3 of the first side wall portion 43 by the horizontal distance d3 of the first side wall portion 43. This may be smaller than a value obtained by dividing the vertical distance h4 of the second side wall portion 44 by the horizontal distance d4 of the second side wall portion 44.

The first side wall portion 43 that is formed in the stairs shape will be described in more detail. The first side wall portion 43 may include a first inclination portion 43a, a second inclination portion 43c, and a planarization portion 43b interposed between the first inclination portion 43a and the second inclination portion 43c. By forming the planarization portion 43b between the first inclination portion 43a and the second inclination portion 43c, the average inclination value of the first side wall portion 43 may be lowered. In an example embodiment, the planarization portion 43b may be formed using a halftone mask, but the method for forming the planarization portion 43b is not limited thereto.

As described above, if the average inclination value is lowered through making of the first side wall portion 43 in the stairs shape, the coverage of the contact layer 65 may be improved. Further, since the average inclination of the second side wall portion 44 is kept as it is, the wiring pattern 52 may be accurately exposed, and thus the contact inferiority may be reduced or prevented from occurring.

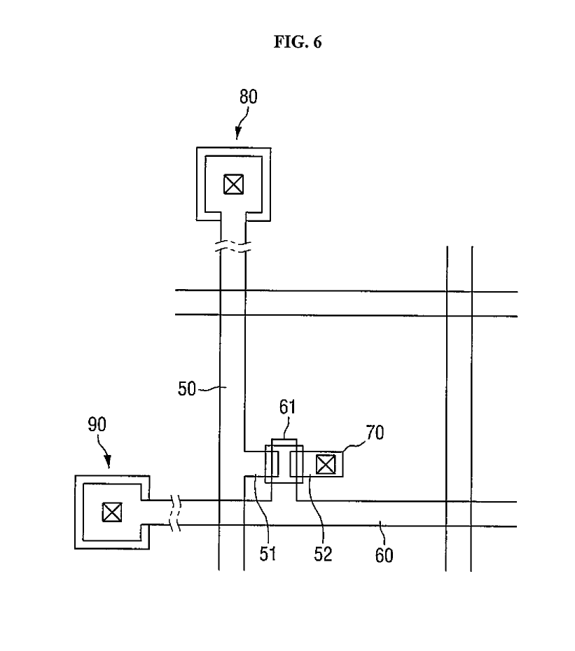

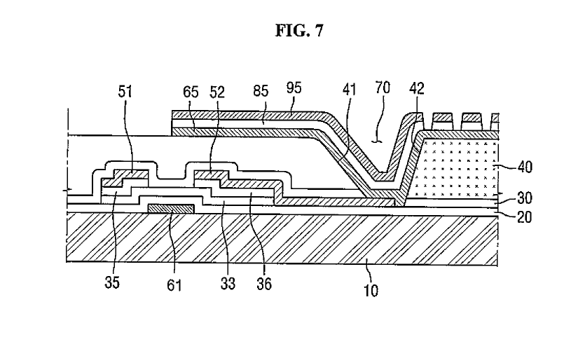

FIG. 6 is a partial plan view of a display device according to still another embodiment of the present invention, and FIG. 7 is a cross-sectional view of the display device of FIG. 6.

Referring to FIGS. 6 and 7, the display device according to this embodiment is different from the display device according to the embodiment of FIG. 1 in that the wiring pattern 52 is the drain electrode, and the display device is a PLS (Plane Line Switching) liquid crystal display.

The display device according to this embodiment may be a Plane Line Switching (PLS) liquid crystal display. However, the scope of the present invention is not limited thereto. The display device according to the present invention may be a liquid crystal display of another kind, such as a Vertical Alignment (VA) liquid crystal display, or an organic light emitting display.

Hereinafter, the display device according another embodiment of the present invention uses a PLS display device as an example.

First, a plurality of gate lines 60 and a plurality of data lines 50 are formed on the substrate 10. As described above, the substrate 10 may be formed of glass or plastic.

A gate line 60 may be formed on the substrate 10. The gate line 60 may include a gate electrode 61 and a gate pad portion 90 for electrical connection with another layer or an external driving circuit. The gate line 60 may be formed to include at least one material selected from the group consisting of aluminum based metal (such as aluminum (Al) or an aluminum alloy), silver based metal (such as silver (Ag) or a silver alloy), copper based metal (such as copper (Cu) or a copper alloy), molybdenum based metal (such as molybdenum (Mo) or a molybdenum alloy), chrome (Cr), tantalum (Ta), and titanium (Ti). The material of the gate lines 60 is not limited thereto, and as a conductive material, a transparent or semitransparent material may be used to form the gate lines 60. The gate line 60 may have a single-layer structure or a multilayer structure including at least two conductive layers having different physical properties.

A gate insulating layer 20 may be formed on the gate line 60. The gate insulating layer 20 may include silicon nitride (SiNx) and/or silicon oxide (SiOx), but the material of the gate insulating layer 20 is not limited thereto. The gate insulating layer 20 may have a single-layer structure, but is not limited thereto. The gate insulating layer 20 may have a multilayer structure including at least two insulating layers having different physical properties.

A semiconductor layer 33 may be formed on the gate insulating layer 20. The semiconductor layer 33 may include amorphous silicon and/or polycrystalline silicon. In the description, the term “semiconductor layer” may include oxide semiconductor, but is not limited thereto.

Ohmic contact members 35 and 36 may be formed on the semiconductor layer 33. The ohmic contact members 35 and 36 may be made of a material of n+ hydrogenated amorphous silicon doped with high-concentration n-channel (n-type) impurity including phosphorus or silicide.

The ohmic contact members 35 and 36 may be arranged as a pair on the semiconductor layer 33. In an example embodiment in which the semiconductor layer 33 includes oxide semiconductor, the ohmic contact members 35 and 36 may be omitted, but are not limited thereto.

On the semiconductor layer 33 and the gate insulating layer 20, data wirings, which include a source electrode 51, a drain electrode 52, and a data line 50, may be formed. The data line 50 may include a data pad portion 80 for connection with another layer or an external driving circuit.

The data line 50 transfers a data signal, and may be arranged to cross the gate line 60. That is, in an example embodiment, the gate line 60 may extend in the horizontal direction and the data line 50 may extend in the vertical direction to cross the gate line 60, but are not limited thereto.

The source electrode 51 is a part of the data line 50, and may be arranged on the same line as the data line 50. The drain electrode 52 may be formed to extend in parallel to the source electrode 51, and in this case, the drain electrode 52 may be in parallel to a part of the data line 50.

The gate electrode 61, the source electrode 51, and the drain electrode 52 form one thin film transistor (TFT) together with the first semiconductor layer 33, and a channel of the thin film transistor may be formed on the semiconductor layer 33 between the source electrode 51 and the drain electrode 52.

The data line 50 may be formed of a refractory metal, such as molybdenum, chrome, tantalum, or titanium, or an alloy thereof, and for example, the data line 50 may have a multilayer structure that includes a refractory metal film and a low-resistance conductive layer. The multilayer structure may include a lower chrome/molybdenum layer and an upper aluminum layer, or may be a triple-layer structure including a lower molybdenum layer, an intermediate aluminum layer, and an upper molybdenum layer. However, the material of the data line 50 is not limited thereto, and transparent or semitransparent material having suitable electrical conductivity may be used to form the data line 50.

The drain electrode 52 may further extend in a direction away from the thin film transistor. An end portion of the extending drain electrode 52 may be arranged on the gate insulating layer 20 to overlap the gate insulating layer 20.

On exposed portions of the data line 50, the gate insulating layer 20, and the semiconductor layer 33, a passivation layer 30 may be arranged. The passivation layer 30 may include an organic insulating material or an inorganic insulating material.

An organic layer 40 may be arranged on the passivation layer 30. The organic layer 40 may be relatively thicker than the passivation layer 30, and in an example embodiment, the organic layer 40 may be a planarization film. That is, the top surface of the organic layer 40 may be flat.

The organic layer 40 may be arranged on a display region where a plurality of pixels are positioned, and may not be positioned on a peripheral region where a gate pad portion 90 or a data pad portion 80 is formed, but is not limited thereto. Further, the thickness of the organic layer 40 in the peripheral region may be different from the thickness of the organic layer 40 in the display region, but the thickness of the organic layer 40 is not limited thereto. Further, in an example embodiment, the organic layer 40 may be omitted.

On the organic layer 40, a contact hole 70, which penetrates the organic layer 40 and exposes at least a portion of the drain electrode 52, may be formed.

If the passivation layer 30 is formed on the drain electrode 52, the contact hole 70 may penetrate the organic layer 40 and the passivation layer 30, and expose at least a portion of the drain electrode 52. Further, in an example embodiment in which the second side wall portion 42 does not overlap the wiring pattern 52, the contact hole 70 may expose at least a portion of the gate insulating layer 20.

The contact hole 70 may be defined (partitioned) by a side wall of the organic layer 40. The side wall of the organic layer 40 may include a first side wall portion 41 and a second side wall portion 42. That is, the contact hole 70 may be defined by the bottom surface, the first side wall portion 41, and the second side wall portion 42. Further, the first side wall portion 41 and the second side wall portion 42 may include an inclined portion that is inclined downward toward the bottom surface. Further, in an example embodiment in which the passivation layer 30 is arranged on the drain electrode 52, the first side wall portion 41 and the second side wall portion 42 may further include the side wall of the passivation layer 30.

The first side wall portion 41 may be arranged on the drain electrode 52. That is, the first side wall portion 41 may be arranged to overlap the drain electrode 52. In other words, the lower end of the first side wall portion 41 may be arranged on the inner side rather than the end portion of the drain electrode 52. The second side wall portion 42 may not overlap the drain electrode 52, and the lower end of the second side wall portion 42 may be spaced apart from the end portion of the drain electrode 52 for a set or predetermined distance.

An average inclination of the first side wall portion 41 and an average inclination of the second side wall portion 42 may be different from each other. That is, a horizontal distance of the first side wall portion 41 may be larger than a horizontal distance of the second side wall portion 42. In this case, the average inclination of the first side wall portion 41 may be less in value than the average inclination of the second side wall portion 42. As described above, the horizontal distance exerts a greater influence on the average inclination than the vertical distance, and the duplicate explanation thereof will not be repeated.

In an example embodiment, the glass transition temperature Tg of the first side wall portion 41 may be different from the glass transition temperature of the second side wall portion 42. This is because in the process of irradiating the UV rays onto the rear surface of the substrate 10 (to be described later), the UV rays irradiated onto the first side wall portion 41 are intercepted by the wiring pattern 52, but the UV rays irradiated onto the second side wall portion 42 are not intercepted, and are irradiated onto the second side wall portion 42 to cure the second side wall portion 42. That is, the glass transition temperature of the second side wall portion 42 may be higher than the glass transition temperature of the first side wall portion 41. If the curing temperature is high, the first side wall portion 41 falls down at least partly to lower the average inclination value in a curing process to be described later, whereas in comparison to the first side wall portion 41, the second side wall portion 42 may keep the average inclination value approximately the same as that prior to the curing.

A first electrode 65 may be arranged on the organic layer 40. That is, the first electrode 65 may be arranged to cover the first side wall portion 41, the second side wall portion 42, and the bottom portion. In other words, the first electrode 65 may come in contact with the drain electrode 52 to be electrically connected to the drain electrode 52. If the first electrode 65 and the drain electrode 52 are electrically connected to each other, the first electrode 65 may receive a voltage from the drain electrode 52.

In an example embodiment, the first electrodes 65 may be pixel electrodes, but are not limited thereto. The first electrode 65 may be made of indium tin oxide (ITO) and/or indium zinc oxide (IZO), but the material of the first electrode 65 is not limited thereto.

In an example embodiment, the first electrode 65 may be a whole surface electrode that covers the whole (or entire) surface of the substrate 10, but is not limited thereto. The first electrode 65 may be formed on a part of the substrate 10 or may be partly formed on the substrate 10.

A passivation layer 85 may be arranged on the first electrode 65. The passivation layer 85 may include an inorganic insulating material, but is not limited thereto. The passivation layer 85 may be conformally formed on the first electrode 65 to cover the first electrode 65 (i.e., the passivation layer 85 and the first electrode 65 have opposing conformal surfaces).

A second electrode 95 may be arranged on the passivation layer 85. In an example embodiment, the second electrode 95 may be a common electrode, but the second electrode is not limited thereto. The second electrode may be made of indium tin oxide (ITO) and/or indium zinc oxide (IZO), but the material of the second electrode 95 is not limited thereto.

Further, the second electrode 95 may be formed to have a plurality of cut patterns. Since it may be apparent to those skilled in the art to form a plurality of cut patterns on the second electrode 95 using (or utilizing) etching or other methods, the detailed explanation thereof will not be repeated to keep the description of the present invention from becoming unclear.

If the first side wall portion 41 and the second side wall portion 42 of the contact hole, in which the drain electrode 52 and the first electrode 65 come in contact with each other, have different average inclination values, the coverage of the first electrode 65 may be improved, and the contact inferiority due to non-opening of the opening may be reduced or prevented from occurring.

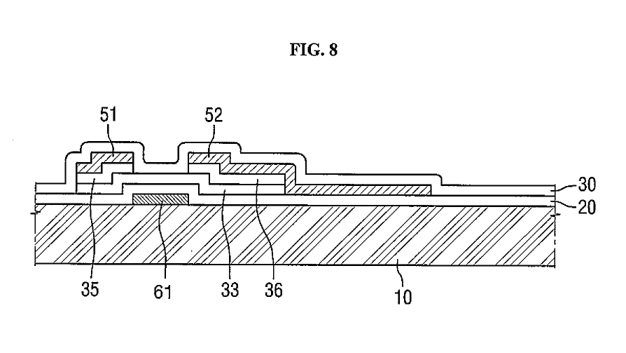

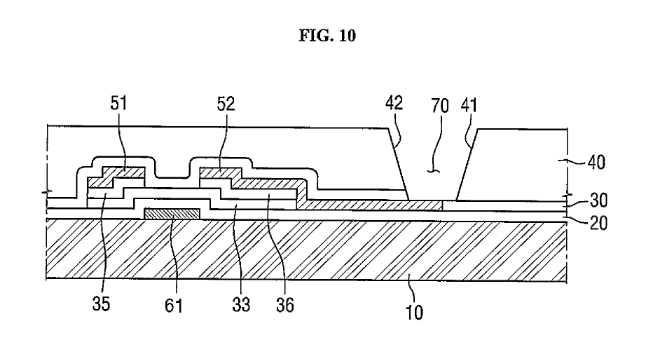

Hereinafter, a method for fabricating a display device according to an embodiment of the present invention will be described. In explaining the method for fabricating a display device according to an embodiment of the present invention, FIGS. 8 to 12 are referred to.

FIGS. 8 to 12 are cross-sectional views illustrating a method for fabricating a display device according to an embodiment of the present invention.

Referring to FIGS. 8 to 12, a method for fabricating a display device according to an embodiment of the present invention includes forming a gate insulating layer 20 on a substrate 10 on which a gate electrode 61 is formed, forming a semiconductor layer 33 on the gate insulating layer 20, and forming a drain electrode 52 that extends from the semiconductor layer 33 to an upper portion of the gate insulating layer 20; forming an organic layer 40 that covers the drain electrode 52 on the drain electrode 52; forming a contact hole 70 which exposes at least a portion of the drain electrode 52 through penetrating the organic layer 40 and which is defined (or partitioned) by a first side wall portion 41, a second side wall portion 42, and a bottom surface; curing the second side wall portion 42 through irradiating ultraviolet rays onto a lower surface of the substrate 10; and lowering an average inclination value of the first side wall portion through curing the organic layer 40.

First, the gate insulating layer 20 may be formed on the substrate 10, and the drain electrode 52 may be formed on the gate insulating layer 20. To explain this, FIG. 8 is referred to. Here, the gate electrode 61 is formed on the substrate 10, and the gate insulating layer 20 is formed on the gate electrode 61. Thereafter, the semiconductor layer 33 is formed on the gate insulating layer 20, and source/drain electrodes 51 and 52 are formed to cover the semiconductor layer 33. Since these processes are substantially equal to those as described above in the display device according to the embodiments of FIGS. 6 and 7, the detailed explanation thereof will not be repeated.

The drain electrode 52 may be formed to extend, and the extended end portion thereof may be arranged on the gate insulating layer 20. Further, a passivation layer 30 that covers the drain electrode 52 may be arranged on the drain electrode 52. As described above, if the passivation layer 30 that covers the drain electrode 52 is formed, the first side wall portion 41 and the second side wall portion 42 may further include a side wall of the passivation layer 30.

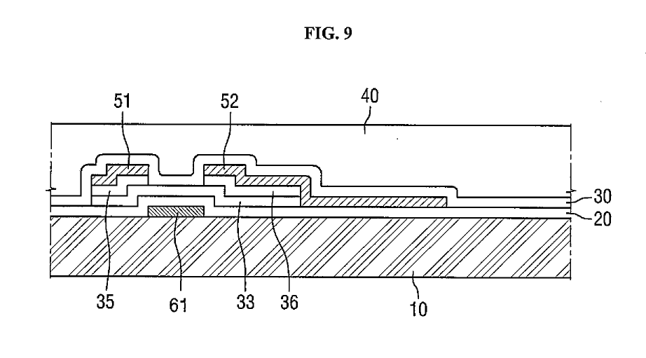

Then, the organic layer 40 that covers the drain electrode 52 may be formed on the drain electrode 52. To explain this, FIG. 9 is referred to. As described above, the organic layer 40 may be relatively thicker than the passivation layer 30, and in an example embodiment, the organic layer 40 may be a planarization film. That is, the top surface of the organic layer 40 may be flat.

Further, as described above, the organic layer 40 may include a material that reacts to light to increase the glass transition temperature of the organic layer 40. This material may be, for example, photo acid generators or radical polymerization monomers. However, the scope of the present invention is not limited thereto. That is, any suitable material, which to light to increases the glass transition temperature of the organic layer 40, may be used as the material of the organic layer 40.

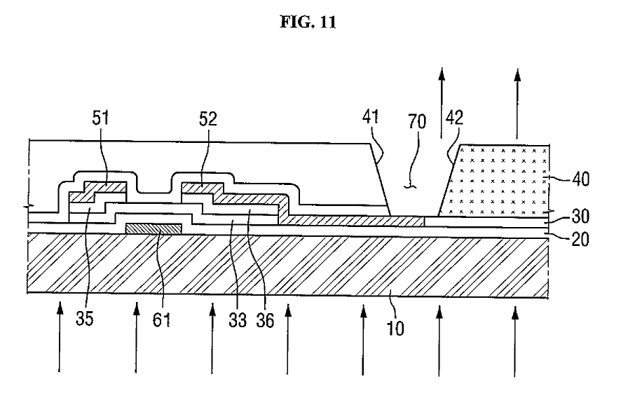

Then, by irradiating UV rays onto the lower surface of the substrate 10, the second side wall portion 42 is cured. To explain this, FIG. 11 is referred to. As described above, the organic layer 40 may include a material that reacts to the light to increase the glass transition temperature of the portion onto which the light is irradiated. In the case of irradiating the UV rays toward the lower surface of the substrate 10, the UV rays that are directed to the first side wall portion 41 may be intercepted by the drain electrode 52 and may not reach the first side wall portion 41. That is, the glass transition temperature of the first side wall portion 41 may not be changed or may be finely changed (i.e., changed slightly). In contrast, the UV rays may be irradiated onto the second side wall portion 42 that does not overlap the drain electrode 52. As described above, if the UV rays are irradiated, the second side wall portion 42 may be cured. In other words, the glass transition temperature of the second side wall portion 42 may be increased. That is, the glass transition temperature of the second side wall portion 42 may be higher than the glass transition temperature of the first side wall portion 41.

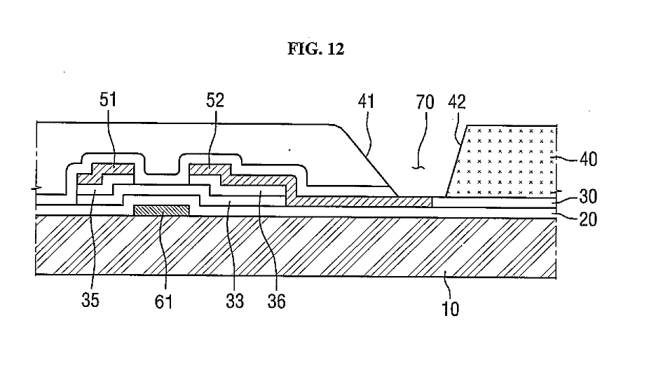

Then, by curing the organic layer 40, the value of the average inclination (or average inclination value) of the first side wall is lowered. To explain this, FIG. 12 is referred to. In an example embodiment, the curing of the organic layer 40 may be performed for about 30 minutes at a temperature of 230° C. However, the curing condition is not limited thereto.

If the curing is performed, the first side wall portion 41 may fall down at least partly due to the high temperature, and thus the average inclination value of the first side wall portion 41 may be lowered. That is, the horizontal distance of the first side wall portion 41 may be increased. However, the second side wall portion 42 that has a higher glass transition temperature than that of the first side wall portion 41 may not be affected or may be relatively less affected by the curing process. Accordingly, if the curing process is performed, the average inclination value of the first side wall portion 41 is lowered, and thus the average inclination values of the first side wall portion 41 and the second side wall portion 42 may be different from each other.

Then, the first electrode may be arranged in the contact hole 70. As described above, if the average inclination values of the first side wall portion 41 and the second side wall portion 42 become different from each other, the coverage of the first electrode may be improved, and the contact inferiority due to clogging of the opening may be reduced or prevented from occurring.

Then, the passivation layer may be arranged on the first electrode, and the second electrode having a plurality of cut patterns may be arranged on the passivation layer. Since the arrangement of the passivation layer on the first electrode and the arrangement of the second electrode having the plurality of cut patterns on the passivation layer may be substantially the same as those described above in the display device according to the embodiments of FIGS. 6 and 7, the detailed explanation thereof will not be repeated.

While the present invention has been particularly shown and described with reference to example embodiments thereof, it will be understood by those of ordinary skill in the art that various changes in form and details may be made therein without departing from the spirit and scope of the present invention as defined by the following claims, and equivalents thereof. It is therefore desired that the present embodiments be considered in all respects as illustrative and not restrictive, reference being made to the appended claims and equivalents thereof, rather than the foregoing description to indicate the scope of the invention.

What is claimed is:

1. A display device comprising:
a substrate;
an insulating layer on the substrate;
a wiring pattern on the insulating layer;
an organic layer on the wiring pattern; and
a contact hole penetrating the organic layer and exposing at least a portion of the wiring pattern,
wherein a side wall of the organic layer defining the contact hole comprises a first side wall portion and a second side wall portion, and an average inclination of the first side wall portion obtained by dividing a vertical distance of the first side wall portion by a horizontal distance of the first side wall portion is different from an average inclination of the second side wall portion obtained by dividing a vertical distance of the second side wall portion by a horizontal distance of the second side wall portion.

2. The display device of claim 1, wherein the horizontal distance of the first side wall portion is greater than the horizontal distance of the second side wall portion.

3. The display device of claim 1, wherein the first side wall portion overlaps the wiring pattern, and the second side wall portion does not overlap the wiring pattern.

4. The display device of claim 1, wherein the average inclination of the first side wall portion is less in value than the average inclination of the second side wall portion.

5. The display device of claim 1, wherein the first side wall portion and the second side wall portion have different glass transition temperatures.

6. The display device of claim 1, wherein the side wall of the organic layer comprises at least one first side wall portion and at least one second side wall portion.

7. The display device of claim 1, further comprising:
a contact layer covering the first side wall portion, the second side wall portion, and a bottom surface of the contact hole, and the contact layer being in contact with the wiring pattern and electrically connected to the wiring pattern.

8. The display device of claim 1, wherein the first side wall portion is in a shape of a stair.

9. The display device of claim 1, wherein the first side wall portion comprises a first inclination portion, a second inclination portion, and a planarization portion between the first inclination portion and the second inclination portion.

10. The display device of claim 1, wherein the insulating layer is a gate insulating layer covering a gate electrode on the substrate, and the wiring pattern extends from a semiconductor layer on the insulating layer to an upper portion of the insulating layer.

11. The display device of claim 10, wherein the wiring pattern comprises a drain, electrode, an end portion of the drain electrode is between the first side wall portion and the second side wall portion, and the contact hole exposes a part of the drain electrode and a part of the insulating layer.

12. The display device of claim 11, further comprising:
a first electrode on the organic layer to cover the first side wall portion, the drain electrode, and the second side wall portion;
a passivation layer on the first electrode to cover the first electrode; and
a common electrode on the passivation layer and having a plurality of cut patterns.

13. The display device of claim 1, further comprising:
a contact layer on the organic layer to cover the first side wall portion, the wiring pattern, and the second side wall portion.

14. The display device of claim 1, wherein the organic layer comprises radical polymerization monomers or photo acid generators.

15. A method for fabricating a display device, the method comprising:
forming a gate insulating layer on a substrate with a gate electrode;
forming a semiconductor layer on the gate insulating layer;
forming a drain electrode to extend from the semiconductor layer to an upper portion of the gate insulating layer;
forming an organic layer on the drain electrode to cover the drain electrode;
forming a contact hole to expose at least a portion of the drain electrode through penetrating the organic layer, the contact hole being defined by a first side wall portion, a second side wall portion, and a bottom surface;
curing the second side wall portion through irradiating ultraviolet rays onto a lower surface of the substrate; and
lowering a value of an average inclination value of the first side wall portion through curing the organic layer.

16. The method for fabricating a display device of claim 15, further comprising:
arranging a first electrode to cover the first side wall portion, the second side wall portion, and the drain electrode, on the organic layer.

17. The method for fabricating a display device of claim 16, further comprising:
arranging a passivation layer on the first electrode; and
arranging a second electrode having a plurality of cut patterns on the passivation layer.
